(19) United States
(12) Patent Application Publication
(10) Pub. No.: US 2026/0076095 A1
(43) Pub. Date: Mar. 12, 2026

(54) ULTRASONIC TRANSDUCER

(71) Applicant: Qisda Corporation, Taoyuan City (TW)

(72) Inventors: Fu-Sheng JIANG, Taoyuan City (TW); Tsung-Chien HUANG, Taoyuan City (TW)

(73) Assignee: Qisda Corporation, Taoyuan City (TW)

(21) Appl. No.: 19/245,599

(22) Filed: Jun. 23, 2025

(30) Foreign Application Priority Data
Sep. 10, 2024 (TW) 113134241

(51) Int. Cl. H10N 30/88; H10N 30/87

(52) U.S. Cl. CPC H10N 30/883; H10N 30/875

(57) ABSTRACT

An ultrasonic transducer is provided. The ultrasonic transducer includes a transducing layer, a first matching layer, a second matching layer and at least one circuit board. The transducing layer is used to transmit and receive an ultrasonic wave. The first matching layer is disposed on a side of the transducing layer adjacent to an object to be measured. The second matching layer is disposed on a side of the first matching layer adjacent to the object to be measured. The circuit board is disposed on the transducing layer, and the circuit board includes a plurality of signal lines, a ground layer and a shielding layer. The signal lines are electrically connected to the transducing layer. The ground layer is disposed around the periphery of the signal lines. The shielding layer surrounds the signal lines and the ground layer.

### BACKGROUND OF THE INVENTION

This application claims the benefit of Taiwan application Serial No. 113134241, filed Sep. 10, 2024, the subject matter of which is incorporated herein by reference.

### Field of the Invention

The present invention relates in general to an ultrasonic transducer, and more particularly, to an ultrasonic transducer including a transducing layer.

### Description of the Related Art

Ultrasonic transducers are crucial diagnostic tools in modern medicine. In handheld ultrasonic transducers, due to the shorter distance to the main board, signals are more susceptible to electromagnetic interference (EMI). Therefore, there remains a strong need to develop an ultrasonic transducer that can reduce the impact of electromagnetic interference.

### SUMMARY OF THE INVENTION

The invention is directed to an ultrasonic transducer in which the design of a ground layer and a shielding layer can reduce the impact of electromagnetic interference.

According to an embodiment of the present invention, an ultrasonic transducer is provided. The ultrasonic transducer comprises a transducing layer, a first matching layer, a second matching layer and at least one circuit board. The transducing layer is used to transmit and receive an ultrasonic wave. The first matching layer is disposed on a side of the transducing layer adjacent to an object to be measured. The second matching layer is disposed on a side of the first matching layer adjacent to the object to be measured. The circuit board is disposed on the transducing layer, and the circuit board includes a plurality of signal lines, a ground layer and a shielding layer. The signal lines are electrically connected to the transducing layer. The ground layer is disposed around the periphery of the signal lines. The shielding layer surrounds the signal lines and the ground layer.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a side view of an ultrasonic transducer according to an embodiment of the present invention, taken from a long-axis direction.

FIG. 2 is a partial side view of the ultrasonic transducer of FIG. 1, taken from a long-axis direction.

FIG. 3 is a perspective view of the ultrasonic transducer of FIG. 1.

FIG. 4 is a partial side view of the ultrasonic transducer of FIG. 1, taken from a short-axis direction.

FIG. 5 is a side view of the ultrasonic transducer of FIG. 1, taken from a short-axis direction.

FIG. 6 is a schematic diagram of a circuit board of an ultrasonic transducer according to an embodiment of the present invention.

FIG. 7 is a side view of an ultrasonic transducer according to another embodiment of the present invention, taken from a short-axis direction.

FIG. 8 is a side view of an ultrasonic transducer according to yet another embodiment of the present invention, taken from a short-axis direction.

### DETAILED DESCRIPTION OF THE INVENTION

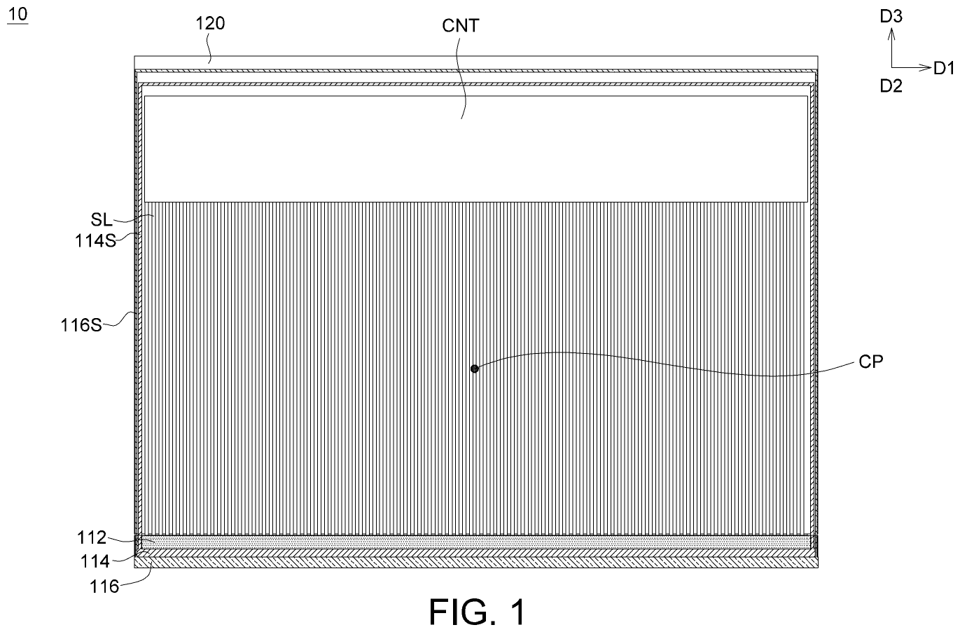

According to an embodiment of the present invention, an ultrasonic transducer 10 is provided, as shown in FIGS. 1-5. In the present embodiment, a long-axis direction of the ultrasonic transducer 10 is, for example, parallel to a first direction D1, and a short-axis direction is, for example, parallel to a second direction D2. The length of the ultrasonic transducer 10 in the long-axis direction (i.e., the first direction D1) is, for example, greater than the length of the ultrasonic transducer 10 in the short-axis direction (i.e., the second direction D2).

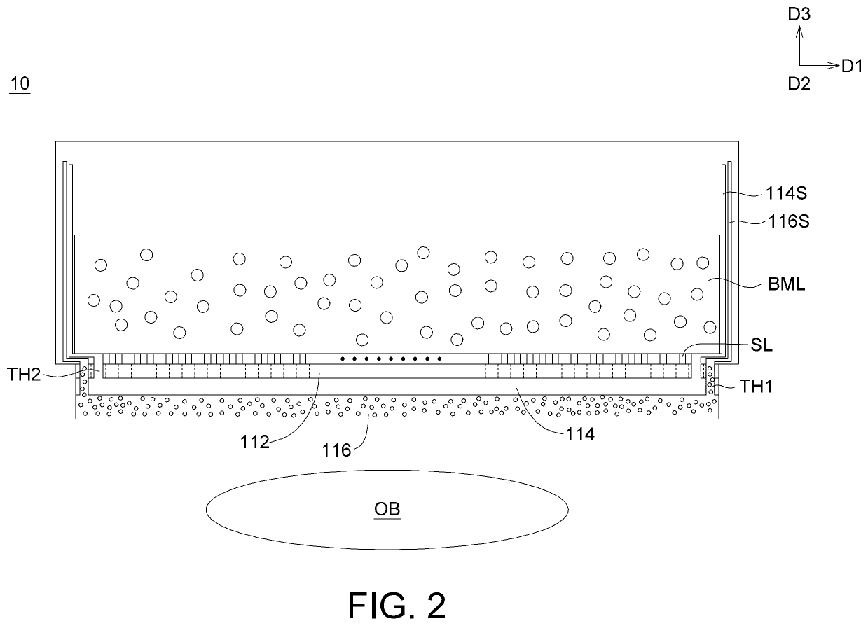

Please refer to FIGS. 1-5 simultaneously. The ultrasonic transducer 10 comprises a transducing layer 112, a first matching layer 114, a second matching layer 116, and at least one circuit board 120. The transducing layer 112 is used to transmit and receive an ultrasonic wave and converts between “electrical energy” and “acoustic energy.” As shown in FIG. 2, the first matching layer 114 is disposed on a side of the transducing layer 112 adjacent to an object OB to be measured. The second matching layer 116 is disposed on a side of the first matching layer 114 adjacent to the OB to be measured.

The ultrasonic transducer 10 further comprises a backing layer BML. The backing layer BML is disposed on a side of the transducing layer 112 away from the object OB to be measured, and the circuit board 120 can partially cover the backing layer BML. In other embodiments, the ultrasonic transducer 10 may comprise more matching layers (not shown). According to some embodiments, the transducing layer 112 may comprise a piezoelectric material. The piezoelectric material is, for example, lead zirconate titanate (PZT), single crystal materials (PMNPT, LiNBO3), quartz, polyvinylidene fluoride (PVDF), aluminum nitride (AlN), and/or zinc oxide, but the present invention is not limited thereto. The first matching layer 114 may have a grounding (GND) property or no grounding property, and the material of the first matching layer 114 may include silver glue, epoxy resin, or other suitable materials. The material of the second matching layer 116 may include epoxy resin, silicone, or other suitable materials. At least one of the first matching layer 114 and the second matching layer 116 comprises metal powder (e.g., aluminum oxide powder, aluminum powder, etc.) to enhance the shielding effect against electromagnetic interference. For example, the material of the first matching layer 114 comprises epoxy resin mixed with metal powder, and the material of the second matching layer 116 comprises epoxy resin mixed with metal powder or silicone mixed with metal powder. In one embodiment, the material of at least one of the first matching layer 114, the second matching layer 116, and the backing layer BML includes a conductive material. In the present embodiment, at least a portion of the material of the first matching layer 114 includes a conductive material; the first matching layer 114 may have a grounding property; at least a portion of the material of the second matching layer 116 includes metal powder; at least a portion of the material of the backing layer BML includes a metal material, wherein the metal material is, for example, metal powder (e.g., aluminum oxide powder, tungsten powder, aluminum powder, iron powder, or titanium powder, etc.) or a metal block (e.g., aluminum or stainless steel). Compared to a comparative example where the second matching layer and the backing layer do not include metal powder, the material of the second matching layer 116 and the backing layer BML of the ultrasonic transducer 10 of the present embodiment includes metal powder, which can provide a better shielding effect against electromagnetic interference.

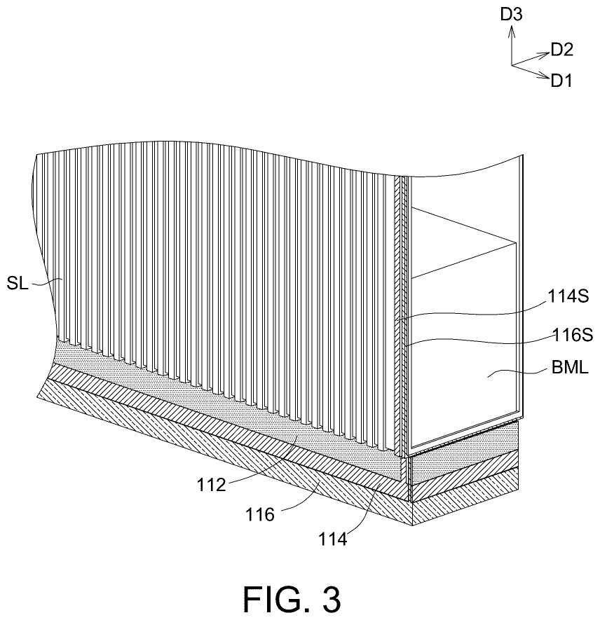

As shown in FIGS. 1-3, the circuit board 120 is disposed on the transducing layer 112, wherein the circuit board 120 includes a plurality of signal lines SL, a ground layer 114S, and a shielding layer 116S. The signal lines SL are electrically connected to the transducing layer 112. The extending direction of the signal lines SL may be at least partially parallel to a third direction D3. The first direction D1, the second direction D2, and the third direction D3 may be perpendicular to each other, but the present invention is not limited thereto. As shown in FIGS. 1 and 3, the ground layer 114S is disposed around the periphery of the signal lines SL, for example, continuously extending around the periphery of the signal lines SL (i.e., the ground layer 114S surrounds the signal lines SL), wherein the extending direction of the ground layer 114S may be partially parallel to the first direction D1 and partially parallel to the third direction D3 (but not limited thereto). Viewed from the long-axis direction (as shown in FIG. 1), the signal lines SL have a center point CP in the region formed by the circuit board 120, and the ground layer 114S is farther away from the center point CP than the signal lines SL. The shielding layer 116S surrounds the signal lines SL and the ground layer 114S. The shielding layer 116S is farther away from the center point CP than the signal lines SL and the ground layer 114S. Since the ground layer 114S is disposed around the periphery of the signal lines SL, providing a first layer of electromagnetic wave protection, and the shielding layer 116S surrounds the signal lines SL and the ground layer 114S, providing a second layer of electromagnetic wave protection, the ultrasonic transducer 10 of the present invention has a double-layer electromagnetic protection design, which can significantly reduce electromagnetic interference.

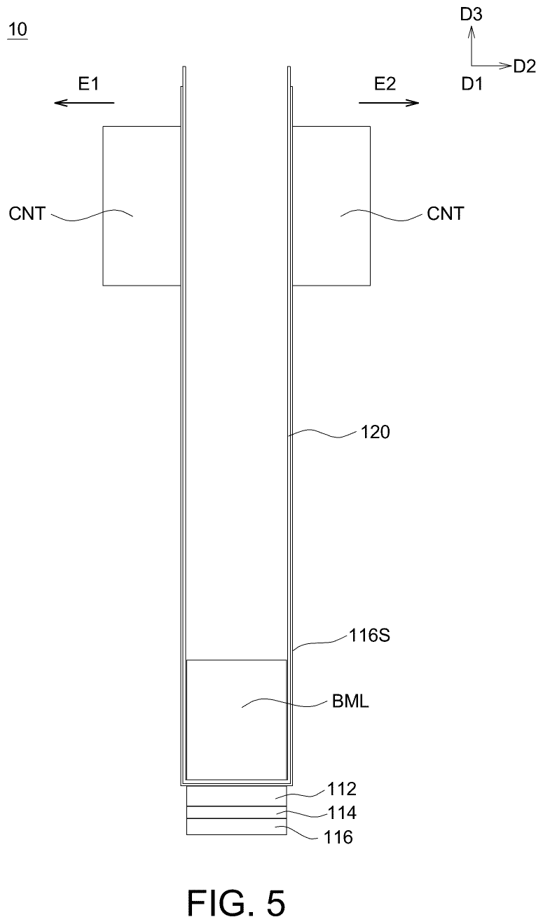

As shown in FIGS. 1-3, the shielding layer 116S is electrically connected to the second matching layer 116 through a first connecting portion TH1, and the first connecting portion TH1 passes through the first matching layer 114 and the transducing layer 112. In the long-axis view, the number of the first connecting portions TH1 is, for example, two, and the two first connecting portions TH1 pass through the opposite side portions of the first matching layer 114 and the transducing layer 112. The material of the first connecting portion TH1 is, for example, identical to the material of the shielding layer 116S. The second matching layer 116, the shielding layer 116S, and the first connecting portion TH1 form a closed loop in the long-axis view (as shown in FIG. 1). The second matching layer 116, the shielding layer 116S, and the first connecting portion TH1 do not form a closed loop in the short-axis view (as shown in FIG. 5), for example, resembling a U-shaped profile. Since the signal lines SL, the ground layer 114S, and the shielding layer 116S can overlap each other in the first direction D1 (as shown in FIGS. 1 and 3), when viewed from the short-axis direction, only the shielding layer 116S is shown, and the signal lines SL and the ground layer 114S are obscured by the shielding layer 116S and not depicted (as shown in FIG. 5). The ground layer 114S is electrically connected to the first matching layer 114 through a second connecting portion TH2, and the second connecting portion TH2 passes through the transducing layer 112. In the long-axis view, the number of the second connecting portions TH2 is, for example, two, and the two second connecting portions TH2 pass through the opposite side portions of the transducing layer 112. The material of the second connecting portion TH2 is, for example, identical to the material of the ground layer 114S. The first matching layer 114, the ground layer 114S, and the second connecting portion TH2 form a closed loop in the long-axis view (as shown in FIG. 1). The materials of the shielding layer 116S, the signal lines SL, and the ground layer 114S may include conductive materials, such as metal.

From the above, it can be seen that the closed loop formed by the first matching layer 114, the ground layer 114S, and the second connecting portion TH2 in the long-axis view can have the electromagnetic shielding effect of a Faraday Cage, providing a first layer of electromagnetic wave protection. The closed loop formed by the second matching layer 116, the shielding layer 116S, and the first connecting portion TH1 in the long-axis view can also have the electromagnetic shielding effect of a Faraday Cage, providing a second layer of electromagnetic wave protection. Therefore, the ultrasonic transducer 10 of the present invention has a double-layer electromagnetic protection design, which has an excellent shielding effect against electromagnetic interference.

According to some embodiments, both the ground layer 114S and the shielding layer 116S have grounding properties, that is, the ground layer 114S serves as a first ground portion in the circuit board 120, and the shielding layer 116S serves as a second ground portion of the circuit board 120.

The circuit board 120 may further include a terminal block CNT, and one end of the signal lines SL away from the transducing layer 112 may be electrically connected to the terminal block CNT. In other embodiments, the circuit board 120 may not include a terminal block CNT, but instead use other methods for the electrical connection of the signal lines SL (e.g., soldering, wire bonding, thermocompression bonding, etc.).

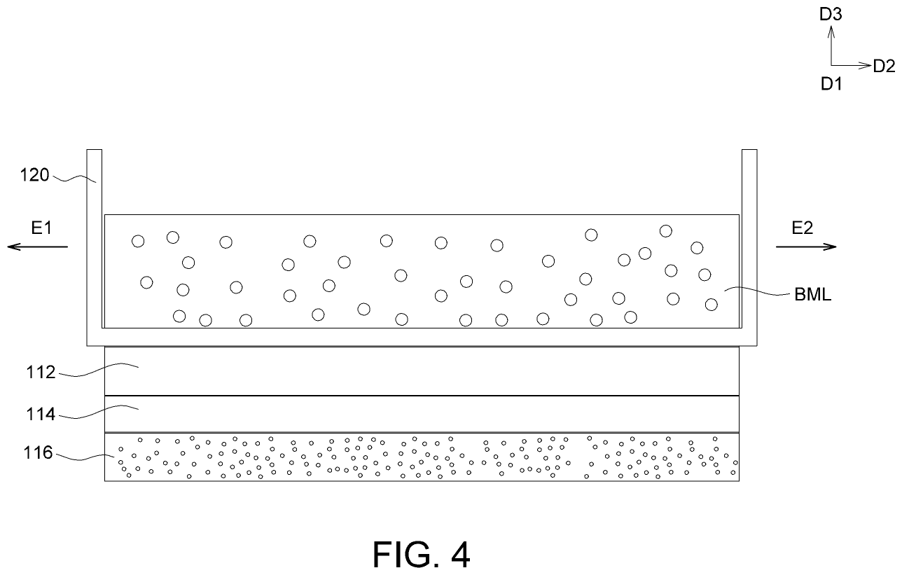

In the present embodiment, the number of circuit boards 120 is two (the present invention is not limited thereto), extending to a first side E1 and a second side E2 of the backing layer BML, the second side E2 being opposite to the first side E1, as shown in FIGS. 4-5. The shielding layers 116S extending to the first side E1 and the second side E2 are connected to each other, the ground layers 114S extending to the first side E1 and the second side E2 are connected to each other, while the signal lines SL extending to the first side E1 and the second side E2 are not connected to each other. The two circuit boards 120 can be connected to each other, as shown in FIGS. 4-5.

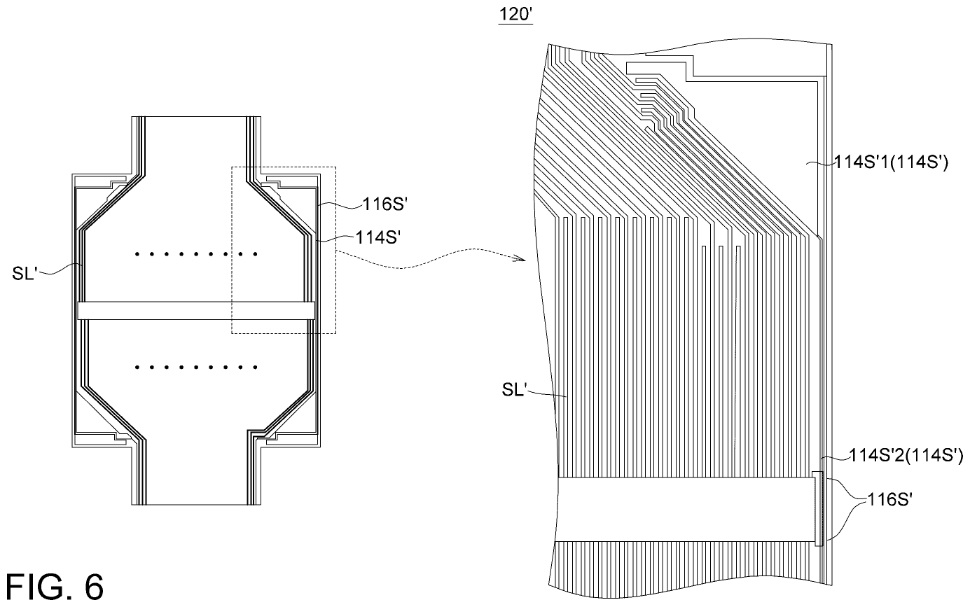

In the present embodiment, the circuit board 120 is depicted as rectangular, and the ground layer 114S and the shielding layer 116S can conform to the contour of the circuit board 120, appearing similar to a rectangle, but the present invention is not limited thereto. The shapes of the circuit board 120, the ground layer 114S, and the shielding layer 116S can be adjusted according to requirements. As shown in FIG. 6, a non-rectangular circuit board 120′ is depicted. The difference between the circuit board 120′ and the circuit board 120 lies in their shapes, and other identical or similar parts will not be described in detail again.

Please refer to FIG. 6. The circuit board 120′ includes a plurality of signal lines SL′, a ground layer 114S′, and a shielding layer 116S′. The materials and functions of the signal lines SL′, the ground layer 114S′, and the shielding layer 116S′ are the same as those of the aforementioned signal lines SL, ground layer 114S, and shielding layer 116S, respectively, and thus will not be described in detail again. The ground layer 114S′ includes a plurality of first extending portions 114S′1 and a plurality of second extending portions 114S′2, and the first extending portions 114S′1 are connected to the second extending portions 114S′2 to surround the signal lines SL′. The first extending portions 114S′1 are, for example, sheet-like, and the second extending portions 114S′2 are, for example, wire-like. The shielding layer 116S′ surrounds the signal lines SL′ and the ground layer 114S′ (including the first extending portions 114S′1 and the second extending portions 114S′2). The shielding layer 116S′ is, for example, wire-like. The circuit boards 120′ extend to the opposite first side E1 and second side E2 (as shown in FIG. 4), and the circuit boards 120′ extending to the first side E1 and the second side E2 are connected to each other, wherein the shielding layers 116S′ extending to the first side E1 and the second side E2 are connected to each other, the ground layers 114S′ extending to the first side E1 and the second side E2 are connected to each other, while the signal lines SL′ extending to the first side E1 and the second side E2 are not connected to each other. In other embodiments, the circuit boards 120′ extending to the first side E1 and the second side E2 are not connected to each other, that is, the shielding layers 116S′ of the circuit boards 120′ extending to the first side E1 and the second side E2 are not connected to each other, and the ground layers 114S′ extending to the first side E1 and the second side E2 are also not connected to each other (not shown).

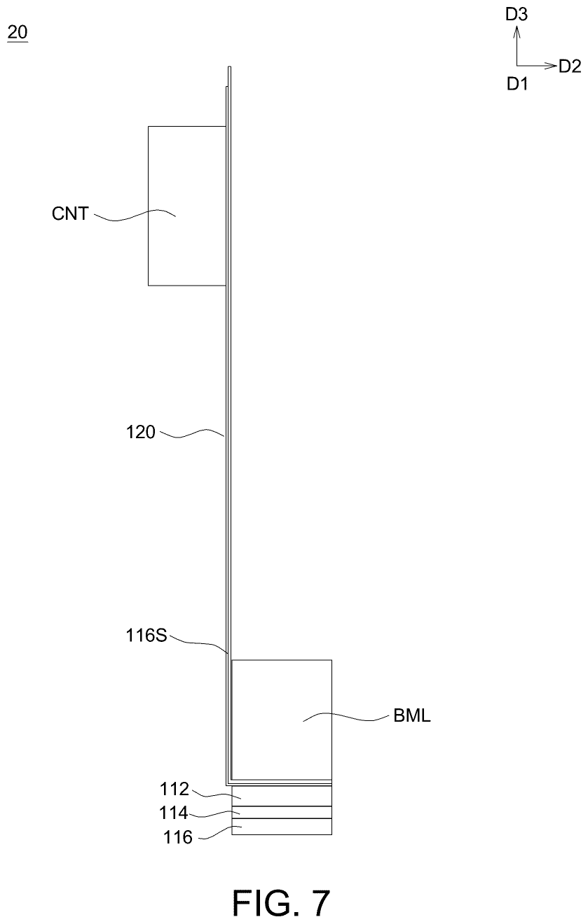

Please refer to FIG. 7. The difference between the ultrasonic transducer 20 and the ultrasonic transducer 10 lies in that the number of circuit board 120 of the ultrasonic transducer 20 is one, disposed on a single side of the backing layer BML, instead of extending to the first side E1 and the second side E2. Other identical or similar parts will not be described in detail again.

The long-axis view of the ultrasonic transducer 20 is as shown in FIGS. 1-2, that is, the closed loop formed by the first matching layer 114, the ground layer 114S, and the second connecting portion TH2 in the long-axis view; and the closed loop formed by the second matching layer 116, the shielding layer 116S, and the first connecting portion TH1 in the long-axis view. The short-axis view of the ultrasonic transducer 20 is as shown in FIG. 7, where the second matching layer 116, the shielding layer 116S, and the first connecting portion TH1 do not form a closed loop in the short-axis view, resembling an L-shaped profile, for example.

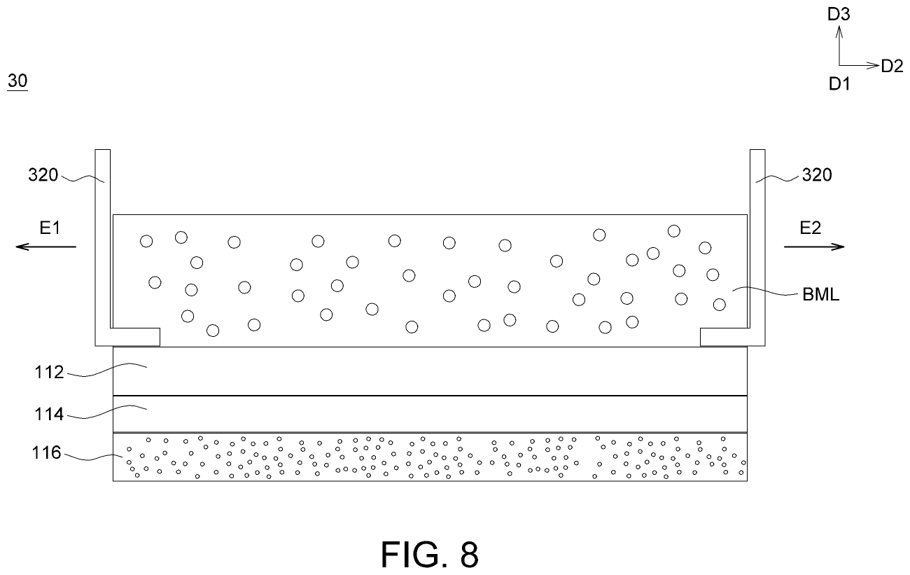

Please refer to FIG. 8. The difference between the ultrasonic transducer 30 and the ultrasonic transducer 10 lies in that the two circuit boards 120 of the ultrasonic transducer 10 are connected to each other (as shown in FIGS. 4-5), but the two circuit boards 320 of the ultrasonic transducer 30 are not connected to each other. Other identical or similar parts will not be described in detail again.

The materials and functions of the ground layer (not shown), the second connecting portion (not shown), the shielding layer (not shown), and the first connecting portion (not shown) of the ultrasonic transducer 30 are the same as or similar to those of the ground layer 114S, the second connecting portion TH2, the shielding layer 116S, and the first connecting portion TH1 of the ultrasonic transducer 10, respectively. The short-axis view of the ultrasonic transducer 30 is as shown in FIG. 8. Since the two circuit boards 320 are not connected to each other, the shielding layers (not shown) of the circuit boards 320 extending to the first side E1 and the second side E2 are not connected to each other, and the ground layers (not shown) extending to the first side E1 and the second side E2 are also not connected to each other.

From the above description, it can be seen that an embodiment of the present invention provides an ultrasonic transducer. The ultrasonic transducer includes a transducing layer, a first matching layer, a second matching layer, and at least one circuit board. The transducing layer is used to transmit and receive an ultrasonic wave. The first matching layer is disposed on a side of the transducing layer adjacent to an object to be measured. The second matching layer is disposed on a side of the first matching layer adjacent to the object to be measured. The circuit board is disposed on the transducing layer, wherein the circuit board includes a plurality of signal lines, a ground layer, and a shielding layer. The signal lines are electrically connected to the transducing layer. The ground layer is disposed around the periphery of the signal lines. The shielding layer surrounds the signal lines and the ground layer. Since the ground layer is disposed around the periphery of the signal lines, providing a first layer of electromagnetic wave protection, and the shielding layer surrounds the signal lines and the ground layer, providing a second layer of electromagnetic wave protection, the ultrasonic transducer of the present invention has a double-layer electromagnetic protection design, which can significantly reduce electromagnetic interference.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An ultrasonic transducer, comprising:
a transducing layer, used to transmit and receive an ultrasonic wave;
a first matching layer, disposed on a side of the transducing layer adjacent to an object to be measured;
a second matching layer, disposed on a side of the first matching layer adjacent to the object to be measured; and
at least one circuit board, disposed on the transducing layer, wherein the circuit board comprises a plurality of signal lines, a ground layer, and a shielding layer, the signal lines are electrically connected to the transducing layer, the ground layer is disposed around periphery of the signal lines, and the shielding layer surrounds the signal lines and the ground layer.

2. The ultrasonic transducer according to claim 1, wherein the shielding layer is electrically connected to the second matching layer through a first connecting portion, and the first connecting portion passes through the first matching layer and the transducing layer.

3. The ultrasonic transducer according to claim 2, wherein the second matching layer, the shielding layer, and the first connecting portion form a closed loop in a long-axis view.

4. The ultrasonic transducer according to claim 2, wherein a number of the first connecting portions is two, and the two first connecting portions pass through opposite side portions of the first matching layer and the transducing layer.

5. The ultrasonic transducer according to claim 2, wherein a material of the first connecting portion is identical to a material of the shielding layer.

6. The ultrasonic transducer according to claim 2, wherein the second matching layer, the shielding layer, and the first connecting portion do not form a closed loop in a short-axis view.

7. The ultrasonic transducer according to claim 6, wherein the second matching layer, the shielding layer, and the first connecting portion resemble a U-shaped profile or a L-shaped profile in the short-axis view.

8. The ultrasonic transducer according to claim 1, wherein the ground layer surrounds the signal lines.

9. The ultrasonic transducer according to claim 8, wherein the ground layer is electrically connected to the first matching layer by a second connecting portion, and the second connecting portion passes through the transducing layer.

10. The ultrasonic transducer according to claim 9, wherein the first matching layer, the ground layer, and the second connecting portion form a closed loop in a long-axis view.

11. The ultrasonic transducer according to claim 9, wherein a number of the second connecting portions is two, and the two second connecting portions pass through opposite side portions of the transducing layer.

12. The ultrasonic transducer according to claim 9, wherein a material of the second connecting portion is identical to a material of the ground layer.

13. The ultrasonic transducer according to claim 1, wherein the ground layer serves as a first ground portion in the circuit board, and the shielding layer serves as a second ground portion of the circuit board.

14. The ultrasonic transducer according to claim 1, further comprising a backing layer disposed on a side of the transducing layer away from the object to be measured, and wherein at least one of the first matching layer, the second matching layer, and the backing layer comprises a conductive material.

15. The ultrasonic transducer according to claim 14, wherein at least one of the first matching layer and the second matching layer comprises metal powder.

16. The ultrasonic transducer according to claim 14, wherein at least a portion of the backing layer comprises a metal material, and the metal material is metal powder or a metal block.

17. The ultrasonic transducer according to claim 1, further comprising a backing layer disposed on a side of the transducing layer away from the object to be measured, wherein a number of the at least one circuit board is two, and the circuit boards extending from a first side and a second side of the backing layer are connected to each other, the second side being opposite to the first side.

18. The ultrasonic transducer according to claim 1, further comprising a backing layer disposed on a side of the transducing layer away from the object to be measured, wherein a number of the at least one circuit board is two, and the circuit boards extending from a first side and a second side of the backing layer are not connected to each other, the second side being opposite to the first side.

19. The ultrasonic transducer according to claim 1, wherein a length of the ultrasonic transducer in a long-axis direction is greater than a length of the ultrasonic transducer in a short-axis direction.

20. The ultrasonic transducer according to claim 1, wherein the signal lines have a center point in a region formed by the at least one circuit board, and the shielding layer is farther away from the center point than the signal lines and the ground layer.
